(19) United States
(12) Patent Application Publication
(10) Pub. No.: US 2025/0147117 A1
(43) Pub. Date: May 8, 2025

(54) APPARATUS AND METHOD FOR DIAGNOSING AND MANAGING STATE OF BATTERY

(71) Applicant: SAMSUNG SDI CO., LTD., Yongin-si (KR)

(72) Inventor: Dolores KIM, Suwon-si (KR)

(21) Appl. No.: 18/616,030

(22) Filed: Mar. 25, 2024

(30) Foreign Application Priority Data
Nov. 3, 2023 (KR) 10-2023-0150497

(51) Int. Cl. G01R 31/396; G01R 31/367; G01R 31/3835; H02J 7/00

(52) U.S. Cl. CPC G01R 31/396; G01R 31/367; G01R 31/3835; H02J 7/0014; H02J 7/0029; H02J 7/0047; H02J 7/007182; H02J 7/007194

(57) ABSTRACT

An apparatus for diagnosing and managing a state of a battery includes a sensing device configured to detect a temperature and a voltage of the battery; and a processor configured to calculate a cell delta voltage based on at least one of the temperature or the voltage of the battery, to calculate a differential value of the temperature, the voltage, or the cell delta voltage, to diagnose an abnormal battery cell or to limit battery charging power based on a threshold value and the differential value.

### CROSS-REFERENCE TO RELATED APPLICATION

This application claims priority to and the benefit of Korean Patent Application No. 10-2023-0150497, filed on Nov. 3, 2023, the disclosure of which is incorporated herein by reference in its entirety.

### BACKGROUND

### 1. Field

Aspects of embodiments of the present disclosure relate to an apparatus and method for diagnosing and managing a state of a battery.

### 2. Description of the Related Art

Generally, a battery pack is composed of a plurality of battery cells, and a battery management system (BMS) monitors the performance and safety of the battery cells.

The battery management system (BMS) monitors the voltage and temperature of the battery cells, and based on this, performs battery cell management, state of charge (SOC) prediction, limitation of input and output power for protection from overheating/overcharging/over-discharging, power relay assembly (PRA) control, fault diagnosis, and the like.

Battery cell management is a function that adjusts the voltage of each cell and manages the battery to prevent overload of the battery. When a specific battery cell malfunctions or does not operate, the battery management system (BMS) performs control so that another battery cell can replace the function of the specific battery cell through cell balancing.

The battery management system (BMS) detects the voltage, current, and temperature of the battery to predict a state of charge, and based on this, allows a battery level to be checked. The SOC sets an upper limit and a lower limit according to a preset availability zone, and in the case of deviating from the availability zone, the battery management system (BMS) blocks the charging of the battery.

To stably operate the battery, an upper limit (i.e., an end-of-charge voltage) and a lower limit (i.e., an end-of-discharge voltage) of the charged battery voltage are set, and the battery management system (BMS) stops charge and discharge of the battery when the voltage of the battery deviates from the end-of-charge voltage or end-of-discharge voltage.

When a high-voltage battery of an electric vehicle malfunctions or becomes uncontrollable, the battery management system (BMS) turns off a relay to block power supply to protect the high-voltage battery and prevent the risk of occurrence of a larger accident.

Further, the battery management system (BMS) diagnoses a malfunction in a battery system, and specifically, detects operational abnormalities such as an overvoltage/undervoltage, a malfunctioning battery cell, a overcurrent condition, an overheating condition, a disconnection, a short circuit, loss of communication, and the like and transmits a diagnostic trouble code (DTC) to another controller.

As described above, the battery management system (BMS) performs diagnosing and managing of the state of the battery cells, and as the performance of these diagnosis and management operations is delayed or the accuracy of determination deteriorates, the greater the risk of an accident occurring.

Accordingly, there is a need for a method for further shortening the time for diagnosing and managing of the state of the battery cells and further improving the accuracy of determination.

The above information disclosed in this Background section is only for enhancement of understanding of the background of the invention and therefore it may contain information that does not form the prior art.

### SUMMARY

Aspects of embodiments of the present invention are directed to providing an apparatus and method for diagnosing and managing a state of a battery capable of shortening the time for diagnosing and managing of the state of battery cells and further improving (e.g., increasing) the accuracy of determination.

Further, aspects of embodiments of the present invention are directed to providing an apparatus and method for diagnosing and managing a state of a battery capable of detecting a temperature of battery cells, extracting a differential value of the temperature, and controlling the temperature of the battery cells according to the extracted differential value to prevent overheating of the battery cells.

In addition, aspects of embodiments of the present invention are directed to providing an apparatus and method for diagnosing and managing a state of a battery capable of determining the occurrence of a cell imbalance based on a differential value of a cell delta voltage and performing cell balancing and current control.

In addition, aspects of embodiments of the present invention are directed to providing an apparatus and method for diagnosing and managing a state of a battery capable of detecting an abnormal cell based on the distribution of a differential value of a cell delta voltage over time to exclude the influence of cell balancing and effectively detect the abnormal cell.

However, technical problems to be solved by the present invention are not limited to the above-described problems, and other problems, which are not mentioned, will be clearly understood by those skilled in the art from the description of the invention disclosed below.

According to some embodiments of the present invention, there is provided an apparatus for diagnosing and managing a state of a battery, the apparatus including: a sensing device configured to detect a temperature and a voltage of the battery; and a processor configured to calculate a cell delta voltage based on at least one of the temperature or the voltage of the battery, to calculate a differential value of the temperature, the voltage, or the cell delta voltage, to diagnose an abnormal battery cell or to limit battery charging power based on a threshold value and the differential value.

In some embodiments, the apparatus further includes: a current blocking device including a switch and configured to block battery charging power based on a control signal from the processor.

In some embodiments, the processor is configured to detect the temperature of the battery, to calculate the differential value of the temperature of the battery, and to limit charging power of the battery based on a result of comparing a specific value and the threshold value, the specific value being expressed as:

$$specific value = α T + β \frac{dT}{dt}$$

where, T is the temperature of the battery, α refers to a weight of the temperature, dT/dt refers to the differential value of the temperature, and β refers to a weight of the differential value.

In some embodiments, the processor is configured to calculate the differential value of the cell delta voltage, and to performs cell balancing or to determines a cell deviation fault based on a result of comparing a specific value and the threshold value, the specific value being expressed as:

$$specific value = α V + β \frac{dV}{dt}$$

where, V is the cell delta voltage, α refers to a weight of the cell delta voltage, dV/dt refers to the differential value of the cell delta voltage, and β refers to a weight of the differential value of the cell delta voltage.

In some embodiments, the processor is configured to calculate the cell delta voltage of the battery, to calculate the differential value of the cell delta voltage in real time, to calculate a distribution and a frequency of the differential value of the cell delta voltage during a period of time, and to diagnose the abnormal battery cell based on a result of comparing the distribution and the frequency of the differential value of the cell delta voltage and first and second distribution threshold values and first and second frequency threshold values.

According to some embodiments of the present invention, there is provided a method of diagnosing and managing a state of a battery, the method including: detecting, by a processor, a temperature of the battery; calculating, by the processor, a differential value of the temperature of the battery; and limiting, by the processor, charging power of the battery based on a result of comparing a threshold value and a specific value calculated from the differential value of the temperature of the battery.

In some embodiments, the processor is configured to calculate a first control amount as the specific value based on Equation 1, the first control amount being expressed as:

$$first control amount = α T + β \frac{dT}{dt}$$

where, T is the temperature of the battery, α refers to a weight of the temperature, dT/dt refers to the differential value of the temperature, and β refers to a weight of the differential value.

In some embodiments, in the comparing of the threshold value and the specific value, the processor is configured to compare the first control amount with a first control threshold value (and a second control threshold value.

In some embodiments, in the limiting of the charging power of the battery based on the result of the comparing, the processor is configured to limit the charging power in response to the first control amount being greater than a first control threshold value.

In some embodiments, in the limiting of the charging power of the battery based on the result of the comparing, the processor is configured to block power input to the battery through a power blocker in response to the first control amount (C1) being greater than a second control threshold value.

According to some embodiments of the present invention, there is provided a method of diagnosing and managing a state of a battery, the method including: calculating, by a processor, a cell delta voltage of the battery; calculating, by the processor, a differential value of the cell delta voltage; and performing, by the processor, cell balancing or determining a cell deviation fault based on a result of comparing a threshold value and a specific value calculated from the differential value of the cell delta voltage.

In some embodiments, the cell delta voltage is a voltage calculated by subtracting a minimum cell voltage value from a maximum cell voltage value.

In some embodiments, the processor is configured to calculate a second control amount as the specific value, the second control amount being expressed as:

$$second control amount = α V + β \frac{dV}{dt}$$

where, V is the cell delta voltage, α refers to a weight of the cell delta voltage, dV/dv refers to the differential value of the cell delta voltage, and β refers to a weight of the differential value of the cell delta voltage.

In some embodiments, in the comparing of the threshold value and the specific value, the processor is configured to compare the second control amount with a third control threshold value and a fourth control threshold value.

In some embodiments, in the performing of the cell balancing, the processor is configured to perform cell balancing in response to the second control amount being greater than a third control threshold value.

In some embodiments, in the determining of the cell deviation fault, the processor is configured to determine the cell deviation fault in response to the second control amount being greater than a fourth control threshold value.

In some embodiments, the method further includes: calculating, by the processor, a distribution and a frequency of the differential value of the cell delta voltage during a period of time; and diagnosing, by the processor, an abnormal battery cell based on a result of comparing the distribution and the frequency of the differential value of the cell delta voltage with first and second distribution threshold values and first and second frequency threshold values.

In some embodiments, the distribution of the differential value of the cell delta voltage includes one of values less than the first distribution threshold value, values greater than or equal to the first distribution threshold value and less than the second distribution threshold value, and values greater than or equal to the second distribution threshold value.

In some embodiments, the frequency of the differential value of the cell delta voltage includes one of a value less than the first frequency threshold value, a value greater than or equal to the first frequency threshold value and less than the second frequency threshold value, and a value greater than or equal to the second frequency threshold value.

In some embodiments, in the diagnosing of the abnormal battery cell, the processor is configured to diagnose a cell with a minimum cell delta voltage value as the abnormal battery cell in response to the frequency of distribution, in which the differential value of the cell delta voltage during the period of time is less than the first distribution threshold value, is greater than the second frequency threshold value, or in response to the frequency of a distribution, which is greater than or equal to the first distribution threshold value and less than the second distribution threshold value, is greater than the first frequency threshold value.

### BRIEF DESCRIPTION OF DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings:

FIG. 1 exemplarily illustrates a schematic configuration of an apparatus for diagnosing and managing a state of a battery according to some embodiments of the present invention;

FIG. 2 exemplarily illustrates a flow diagram for describing a method of diagnosing and managing a state of a battery according to some embodiments of the present invention;

FIG. 3 exemplarily illustrates a flow diagram for describing a method of diagnosing and managing a state of a battery according to some other embodiments of the present invention; and

FIG. 4 exemplarily illustrates a flow diagram for describing a method of diagnosing and managing a state of a battery according to still some other embodiments of the present invention.

### DETAILED DESCRIPTION

Hereinafter, some embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

References to two comparable elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

When an arbitrary element is referred to as being disposed (or located or positioned) on the “above (or below)” or “on (or under)” a component, it may mean that the arbitrary element is placed in contact with the upper (or lower) surface of the component and may also mean that another component may be interposed between the component and any arbitrary element disposed (or located or positioned) on (or under) the component.

In addition, it will be understood that when an element is referred to as being “coupled,” “linked” or “connected” to another element, the elements may be directly “coupled,” “linked” or “connected” to each other, or an intervening element may be present therebetween, through which the element may be “coupled,” “linked” or “connected” to another element. In addition, when a part is referred to as being “electrically coupled” to another part, the part can be directly connected to another part or an intervening part may be present therebetween such that the part and another part are indirectly connected to each other.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

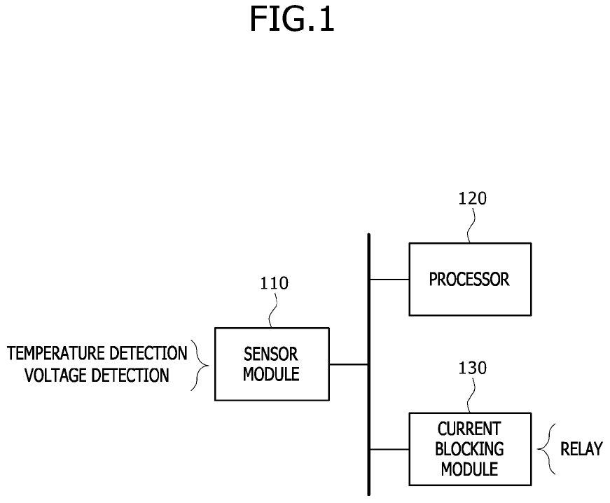

FIG. 1 is an exemplary diagram illustrating a schematic configuration of an apparatus for diagnosing and managing a state of a battery according to some embodiments of the present invention.

Referring to FIG. 1, the apparatus for diagnosing and managing the state of the battery according to some embodiments of the present invention includes a sensing device (e.g., a sensor module) 110, a processor 120, and a current blocking device (e.g., a current blocking module) 130.

The sensor device 110 includes a temperature sensor which detects a temperature of a battery or a battery cell of the battery.

The sensing device 110 includes a voltage sensor which detects a voltage of the battery or battery cell.

The processor 120 may calculate a cell delta voltage, that is, a difference between the maximum cell voltage value and the minimum cell voltage value of the battery. In some examples, the maximum and minimum cell voltage values may refer to the highest and lowest cell voltage values that are measured/sensed by the time of calculating the cell delta voltage.

The processor 120 may calculate a differential value (e.g., a time derivative) of the temperature, voltage, or cell delta voltage of the battery or battery cell detected through the sensing device 110.

The processor 120 may diagnose an abnormal battery cell or limit power (i.e., power input to charge the battery cell) by comparing a value calculated by a specified equation based on the differential value (referred to as a control amount C for convenience) and a plurality of threshold values (e.g., pre-specified threshold values, such as a first threshold value and a second threshold value).

The current blocking device 130 blocks the power input to charge the battery cell according to a control signal from the processor 120.

In some embodiments, the current blocking device 130 includes a switch, which may block flow of current into or out of the battery by opening/becoming deactivated, and permitting flow of current into or out of the battery by closing/becoming activated. However, embodiments of the present disclosure are not limited thereto, and the current blocking device 130 may have any suitable circuit configuration. The switch may include a mechanical relay, one or more field effect transistors (FETs), and/or the like.

Hereinafter, operations of diagnosing and managing the state of the battery (i.e., a concept including the battery and the battery cell) by the processor 120 will be described in more detail.

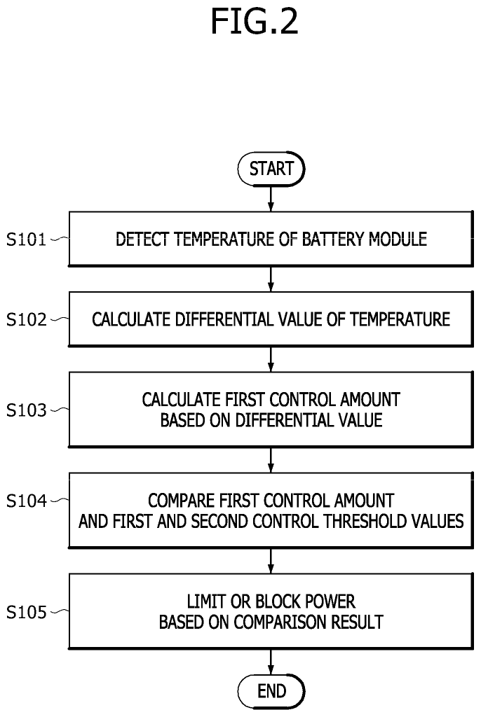

FIG. 2 is a flow diagram for describing a method of diagnosing and managing a state of a battery according to some embodiments of the present invention.

Referring to FIG. 2, the processor 120 detects a temperature T of a battery (S101).

The processor 120 calculates a differential value (e.g., a time derivative dT/dt) of the detected temperature T of the battery (S102).

The processor 120 calculates a specific value (also referred to as a first control amount C1 for convenience) by substituting the differential value (dT/dt) into the following Equation 1 (S103).

$$first control amount = α T + β \frac{dT}{dt} \qquad Equation 1$$

where, T is the temperature of the battery, α refers to a weight of the temperature, dT/dt refers to a differential value of the temperature, and β refers to a weight of the differential value, and α and β may be set in advance using experimental data.

The processor 120 compares the first control amount C1 and first and second control threshold values (e.g., pre-specified first and second control threshold values) CONTROL_THRESHOLD1 and CONTROL_THRESHOLD2 (S104). Here, the first control threshold value CONTROL_THRESHOLD1 is a value less than the second control threshold value CONTROL_THRESHOLD2.

As a result of the comparison (S104), when the first control amount C1 is greater than the first control threshold value CONTROL_THRESHOLD1 and is less than or equal to the second control threshold value CONTROL_THRESHOLD2 (i.e., CONTROL_THRESHOLD1<first control amount C1≤CONTROL_THRESHOLD2), the processor 120 limits the power (i.e., power input to charge the battery cell). When the first control amount C1 is greater than the second control threshold value CONTROL_THRESHOLD2 (i.e., first control amount C1>CONTROL_THRESHOLD2), power input to the battery through the current blocking device 130 (e.g., the switch) is blocked (e.g., the switch is opened; S105).

As described above, in some embodiments, because it is determined that the temperature tends to rise quickly as the differential value (dT/dt) of the temperature T of the battery increases even when the temperature T of the battery does not reach a temperature threshold value TEMP_THRESHOLD, a rise in temperature may be prevented or substantially reduced by allowing current limiting (or current blocking) to be performed early even when the temperature T of the battery does not reach the temperature threshold value TEMP_THRESHOLD.

In some embodiments, there is an effect that battery overheating prevention performance can be improved by determining the battery overheating possibility early to prevent the temperature of the battery from reaching an extreme temperature.

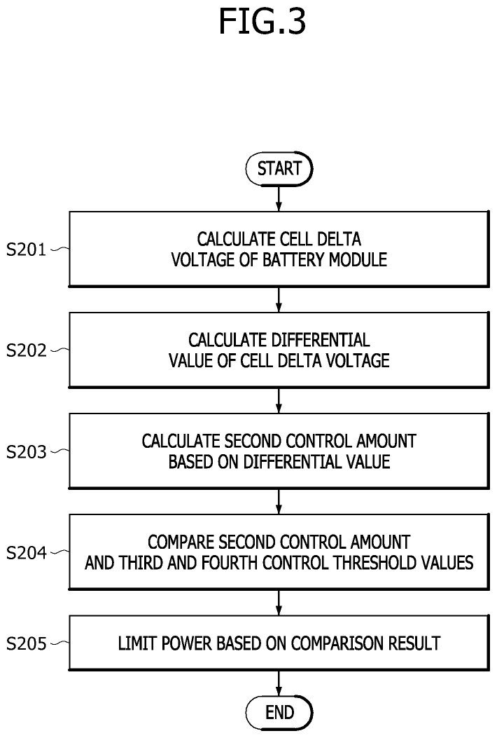

FIG. 3 is a flow diagram for describing a method of diagnosing and managing a state of a battery according to some other embodiments of the present invention.

Referring to FIG. 3, the processor 120 detects a cell delta voltage, that is, a difference between the maximum cell voltage value and the minimum cell voltage value of the battery (S201). In some examples, the maximum and minimum cell voltage values may refer to the highest and lowest cell voltage values that are measured/sensed by the time of calculating the cell delta voltage. The processor 120 calculates a differential value (e.g., a time derivative dV/dt) of the cell delta voltage V (S202).

The processor 120 calculates a specific value (also referred to as a second control amount C2 for convenience) by substituting the differential value (dV/dt) of the cell delta voltage into the following Equation 2 (S203).

$$second control amount = α V + β \frac{dV}{dt} \qquad Equation 2$$

where, V is the cell delta voltage, α refers to a weight of the cell delta voltage, dV/dt refers to the differential value of the cell delta voltage, and β refers to a weight of the differential value of the cell delta voltage, and α and β may be set in advance using experimental data.

The processor 120 compares the second control amount C2 and third and fourth control threshold values (e.g., pre-specified third and fourth control threshold values) CONTROL_THRESHOLD3 and CONTROL_THRESHOLD4 (S204). Here, the third control threshold value CONTROL_THRESHOLD3 is a value less than the fourth control threshold value CONTROL_THRESHOLD4.

As a result of the comparison (S204), when the second control amount C2 is greater than the third control threshold value CONTROL_THRESHOLD3 and less than or equal to the fourth control threshold value CONTROL_THRESHOLD4 (i.e., CONTROL_THRESHOLD3<second control amount C2≤ CONTROL_THRESHOLD4), the processor 120 performs cell balancing. When the second control amount C2 is greater than the fourth control threshold value CONTROL_THRESHOLD4 (i.e., second control amount C2>CONTROL_THRESHOLD4), the processor 120 determines the condition to be a cell deviation fault (S205).

As described above, in some embodiments, because it is determined that a voltage difference between cells tends to increase quickly as the differential value (dV/dt) of the cell delta voltage V increases even when the cell delta voltage V does not reach a voltage threshold value V_THRESHOLD, the voltage difference between cells is decreased by allowing cell balancing to be performed early.

In some embodiments, there is an effect that cell imbalance detection performance can be improved even in a cell voltage fluctuation situation.

In some examples, when there is an abnormal battery cell, the abnormal battery cell may be detected using the cell delta voltage.

In such examples, the voltage of the abnormal battery cell decreases more quickly than the voltages of other battery cells, and in this case, the cell delta voltage may be reduced by performing cell balancing. However, because the voltage in the abnormal battery cell quickly decreases and thus the cell delta voltage increases again, that is, because the cell delta voltage quickly increases and decreases even when there is the abnormal battery cell, there is a problem in that diagnosis (determination) of the abnormal battery cell is delayed.

That is, because the cell delta voltage is maintained within a range (e.g., a specified range) by cell balancing even when the abnormal battery cell is diagnosed, there is a problem in that the timing of the diagnosis (determination) of the abnormal battery cell may be delayed.

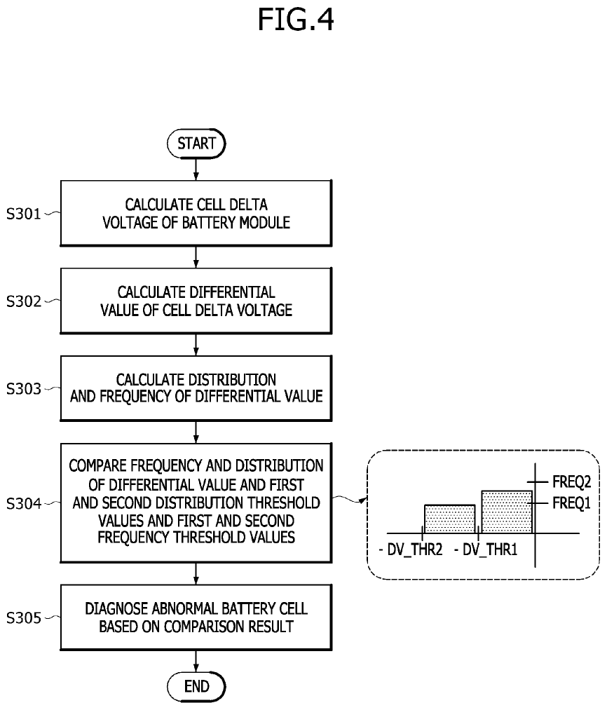

Accordingly, a method capable of detecting an abnormal battery cell without being influenced by cell balancing will be described with reference to FIG. 4.

FIG. 4 is a flow diagram for describing a method of diagnosing and managing a state of a battery according to still other embodiments of the present invention.

Referring to FIG. 4, the processor 120 detects a cell delta voltage, that is, a difference between the maximum cell voltage value and the minimum cell voltage value of the battery (S301). In some examples, the maximum and minimum cell voltage values may refer to the highest and lowest cell voltage values that are measured/sensed by the time of calculating the cell delta voltage.

The processor 120 calculates a differential value (dV/dt) of the cell delta voltage V in real time (S302).

Here, V is the cell delta voltage, and dt is a unit time (e.g., 10 ms to 100 ms).

The processor 120 calculates the distribution and frequency of the differential value (dV/dt) of the cell delta voltage V during a period of time (e.g., one second) (S303).

In this case, because a voltage decrease rate is important for diagnosing an abnormal battery cell, the distribution and frequency may be calculated only for the voltage decrease rate.

The processor 120 compares the distribution and frequency of the differential value (dV/dt) of the cell delta voltage V and first and second distribution threshold values (e.g., pre-specified first and second distribution threshold values) DV_THR1 and DV_THR2 and first and second frequency threshold values FREQ1 and FREQ2 (S304).

Here, the second distribution threshold value DV_THR2 is a value greater than the first distribution threshold value DV_THR1, and the second frequency threshold value FREQ2 is a value greater than the first frequency threshold value FREQ1.

For example, the distribution of the differential value (dV/dt) of the cell delta voltage V during a period of time (e.g., one second) is one of values less than the first distribution threshold value DV_THR1, values greater than or equal to the first distribution threshold value DV_THR1 and less than the second distribution threshold value DV_THR2, and values greater than or equal to the second distribution threshold value DV_THR2. Further, the frequency of the differential value (dV/dt) of the cell delta voltage V during a period of time (e.g., one second) is one of a value less than the first frequency threshold value FREQ1, a value greater than or equal to the first frequency threshold value FREQ1 and less than the second frequency threshold value FREQ2, and a value greater than or equal to the second frequency threshold value FREQ2.

As a result of the comparison (S304), the processor 120 diagnoses a cell with a minimum cell delta voltage value as the abnormal battery cell when the frequency of the distribution, in which the differential value (dV/dt) of the cell delta voltage V during a period of time (e.g., one second) is less than the first distribution threshold value DV_THR1 is greater than the second frequency threshold value FREQ2, or when the frequency of the distribution, which is greater than or equal to the first distribution threshold value DV_THR1 and less than the second distribution threshold value DV_THR2, is greater than the first frequency threshold value FREQ1 (S305).

In some embodiments, the distribution of the differential value of the cell delta voltage over time is accumulated for a period of time to diagnose an abnormal battery cell according to the accumulated frequency for each distribution. That is, in some embodiments, there is an effect of allowing diagnosis of an abnormal battery cell without being influenced by cell balancing by diagnosing the abnormal battery cell based on the frequency for each distribution of the differential value of the cell delta voltage over time.

Embodiments described in the present specification may be implemented as, for example, as a method or process, device, software program, data stream, or signal. Although only the context of a singular form of implementation is discussed (e.g., only a method is discussed), implementations of discussed features may also be implemented in another form (e.g., a device or program). The device may be implemented with appropriate hardware, software, firmware, and the like. The method may be implemented in devices such as processors, which generally refer to processing devices that include computers, microprocessors, integrated circuits, programmable logic devices, or the like. Further, the processors include communication devices such as computers, cellular phones, portable/personal digital assistants (PDAs), other devices, etc. that facilitate the communication of information between end-users.

According to some embodiments of the present invention, the time for diagnosing and managing of the state of battery cells can be shortened and the accuracy of determination can be further improved.

Further, according to some embodiments of the present invention, a temperature of the battery cells is detected, a differential value of the temperature is extracted, and the temperature of the battery cells is controlled according to the extracted differential value to prevent overheating of the battery cells.

In addition, according to some embodiments of the present invention, the occurrence of a cell imbalance can be determined based on a differential value of a cell delta voltage to perform cell balancing and current control.

In addition, according to some embodiments of the present invention, an abnormal cell can be detected based on distribution of a differential value of the cell delta voltage over time to exclude the influence of cell balancing and effectively detect the abnormal cell.

However, effects, which can be acquired through the present invention, are not limited to the above-described effects, and other technical effects, which are not mentioned, will be clearly understood by those skilled in the art from the description of the invention described above.

Although the present invention has been described with reference to the embodiments shown in the drawings, these are merely exemplary, and it should be understood by those skill in the art that various modifications and equivalents are possible. Accordingly, the technical scope of the present invention should be defined by the following claims and equivalents thereof.

What is claimed is:

1. An apparatus for diagnosing and managing a state of a battery, the apparatus comprising:
a sensing device configured to detect a temperature and a voltage of the battery; and
a processor configured to calculate a cell delta voltage based on at least one of the temperature or the voltage of the battery, to calculate a differential value of the temperature, the voltage, or the cell delta voltage, to diagnose an abnormal battery cell or to limit battery charging power based on a threshold value and the differential value.

2. The apparatus of claim 1, further comprising:
a current blocking device comprising a switch and configured to block battery charging power based on a control signal from the processor.

3. The apparatus of claim 1, wherein the processor is configured to detect the temperature of the battery, to calculate the differential value of the temperature of the battery, and to limit charging power of the battery based on a result of comparing a specific value and the threshold value, the specific value being expressed as:
$$specific value = α T + β \frac{dT}{dt}$$
where, T is the temperature of the battery, α refers to a weight of the temperature, dT/dt refers to the differential value of the temperature, and β refers to a weight of the differential value.

4. The apparatus of claim 1, wherein the processor is configured to calculate the differential value of the cell delta voltage, and to performs cell balancing or to determines a cell deviation fault based on a result of comparing a specific value and the threshold value, the specific value being expressed as:
$$specific value = α V + β \frac{dV}{dt}$$
where, V is the cell delta voltage, α refers to a weight of the cell delta voltage, dV/dt refers to the differential value of the cell delta voltage, and β refers to a weight of the differential value of the cell delta voltage.

5. The apparatus of claim 1, wherein the processor is configured to calculate the cell delta voltage of the battery, to calculate the differential value of the cell delta voltage in real time, to calculate a distribution and a frequency of the differential value of the cell delta voltage during a period of time, and to diagnose the abnormal battery cell based on a result of comparing the distribution and the frequency of the differential value of the cell delta voltage and first and second distribution threshold values and first and second frequency threshold values.

6. A method of diagnosing and managing a state of a battery, the method comprising:
detecting, by a processor, a temperature of the battery;
calculating, by the processor, a differential value of the temperature of the battery; and
limiting, by the processor, charging power of the battery based on a result of comparing a threshold value and a specific value calculated from the differential value of the temperature of the battery.

7. The method of claim 6, wherein the processor is configured to calculate a first control amount as the specific value based on Equation 1, the first control amount being expressed as:
$$first control amount = α T + β \frac{dT}{dt}$$
where, T is the temperature of the battery, α refers to a weight of the temperature, dT/dt refers to the differential value of the temperature, and β refers to a weight of the differential value.

8. The method of claim 7, wherein, in the comparing of the threshold value and the specific value, the processor is configured to compare the first control amount with a first control threshold value (and a second control threshold value.

9. The method of claim 7, wherein, in the limiting of the charging power of the battery based on the result of the comparing, the processor is configured to limit the charging power in response to the first control amount being greater than a first control threshold value.

10. The method of claim 7, wherein, in the limiting of the charging power of the battery based on the result of the comparing, the processor is configured to block power input to the battery through a power blocker in response to the first control amount (C1) being greater than a second control threshold value.

11. A method of diagnosing and managing a state of a battery, the method comprising:
calculating, by a processor, a cell delta voltage of the battery;
calculating, by the processor, a differential value of the cell delta voltage; and
performing, by the processor, cell balancing or determining a cell deviation fault based on a result of comparing a threshold value and a specific value calculated from the differential value of the cell delta voltage.

12. The method of claim 11, wherein the cell delta voltage is a voltage calculated by subtracting a minimum cell voltage value from a maximum cell voltage value.

13. The method of claim 11, wherein the processor is configured to calculate a second control amount as the specific value, the second control amount being expressed as:
$$second control amount = α V + β \frac{dV}{dt}$$
where, V is the cell delta voltage, α refers to a weight of the cell delta voltage, dV/dt refers to the differential value of the cell delta voltage, and [symbol] refers to a weight of the differential value of the cell delta voltage.

14. The method of claim 13, wherein, in the comparing of the threshold value and the specific value, the processor is configured to compare the second control amount with a third control threshold value and a fourth control threshold value.

15. The method of claim 13, wherein, in the performing of the cell balancing, the processor is configured to perform cell balancing in response to the second control amount being greater than a third control threshold value.

16. The method of claim 13, wherein, in the determining of the cell deviation fault, the processor is configured to determine the cell deviation fault in response to the second control amount being greater than a fourth control threshold value.

17. The method of claim 11, further comprising:
calculating, by the processor, a distribution and a frequency of the differential value of the cell delta voltage during a period of time; and
diagnosing, by the processor, an abnormal battery cell based on a result of comparing the distribution and the frequency of the differential value of the cell delta voltage with first and second distribution threshold values and first and second frequency threshold values.

18. The method of claim 17, wherein the distribution of the differential value of the cell delta voltage comprises one of values less than the first distribution threshold value, values greater than or equal to the first distribution threshold value and less than the second distribution threshold value, and values greater than or equal to the second distribution threshold value.

19. The method of claim 17, wherein the frequency of the differential value of the cell delta voltage comprises one of a value less than the first frequency threshold value, a value greater than or equal to the first frequency threshold value and less than the second frequency threshold value, and a value greater than or equal to the second frequency threshold value.

20. The method of claim 17, wherein, in the diagnosing of the abnormal battery cell, the processor is configured to diagnose a cell with a minimum cell delta voltage value as the abnormal battery cell in response to the frequency of distribution, in which the differential value of the cell delta voltage during the period of time is less than the first distribution threshold value, is greater than the second frequency threshold value, or in response to the frequency of a distribution, which is greater than or equal to the first distribution threshold value and less than the second distribution threshold value, is greater than the first frequency threshold value.
